(19) United States
(12) Patent Application Publication
(10) Pub. No.: US 2014/0244192 A1
(43) Pub. Date: Aug. 28, 2014

(54) SYSTEM AND METHOD FOR PROVIDING MONITORING OF INDUSTRIAL EQUIPMENT

(71) Applicant: InScope Energy, LLC, Reston, VA (US)

(72) Inventors: Jason Craig, Haymarket, VA (US); William Pugh, Bethesda, MD (US); Richard Daniel Albarran, Fairfax, VA (US)

(73) Assignee: InScope Energy, LLC, Reston, VA (US)

(21) Appl. No.: 13/776,407

(22) Filed: Feb. 25, 2013

(51) Int. Cl. G01R 21/06

(52) U.S. Cl. CPC G01R 21/06
USPC 702/62; 702/61

(57) ABSTRACT

A system and method for providing monitoring of industrial equipment is disclosed. In such a system and method, one or more sensor units may be configured to generate output signals conveying information regarding power conducted to the industrial equipment. One or more power parameters may be determined based on the sensor output signals. Abnormal operations of the industrial equipment may be determined based on the power parameters and alerts responsive to the abnormal operations may be generated. In some embodiments, information regarding a present operation of the industrial equipment may be received from a control system and/or monitoring system. In those embodiments, a fault or a likelihood of fault of the control system and/or the monitoring system may be determined.

### FIELD OF THE INVENTION

The invention relates to providing industrial security based on power measurements of industrial equipment.

### BACKGROUND OF THE INVENTION

Industrial control processes, such as those of manufacturing, production, power generation, fabrication, natural resource (e.g., gas) pumping, refining or the like, are known. In industrial control processes, industrial equipment may be controlled by a control system, for example, such as a supervisory control and data acquisition system (SCADA) remotely from the site where the industrial equipment is located. Intrusions, like STUXNET, AURORA and etc., on industrial equipment through such a control system have been well documented. Typically, these intrusions attack the industrial equipment by hijacking the control system and instruct the control system to control the industrial equipment in ways that cause the industrial equipment to operate abnormally (e.g., instructing the equipment to spin its motor continuously until explosion). When the industrial equipment is under such an attack, it is difficult to detect the intrusion because the monitoring provided by the control system typically has already been compromised by the intrusion.

### SUMMARY

One aspect of the invention relates to a system and method that provides monitoring of industrial equipment based on power measurements (for example, such as power usage) of the industrial equipment. In such a system and method, one or more sensor units may be configured to be connected to power lines that conduct power to the industrial equipment. The sensor units may be configured to generate output signal conveying information related to power conducted to the industrial equipment. Based on the output signals generated by the sensor units, values for one or more of power parameters may be determined. The values for the power parameters may be used to identify an abnormal operation of the industrial equipment by comparing them with one or more thresholds (e.g., measurement points) and/or patterns (e.g., over a period of time). In the event when abnormal operations of the industrial equipment are identified, one or more alerts may be generated. This may provide a reliable way for detecting abnormal operations of the industrial equipment caused by, for example, intrusions on the industrial equipment, virus and/or malware introduced by an operator of the industrial equipment, faulty programming of the industrial equipment, equipment failure (e.g., limit switch fails, pressure switch fails, etc.) and/or any other events.

Another aspect of the invention relates to facilitating a detection of a malfunction of a control system and/or a monitoring system that is configured to control and/or monitor the industrial equipment. Information about present operations of the industrial equipment may be collected from the control system and/or monitory system. In the event when such information fails to indicate a different operational state of the industrial equipment from that indicated by the disclosed system and method, alerts may be generated to notify a fault or likelihood of a fault suffered by the control system and/or monitor system (e.g., the control system may be under a cyber-attack).

The system may include one or more of a sensor unit, one or more of a processor and/or other components. The sensor unit may be configured to be connected to a power line that conducts power to a piece of industrial equipment. The sensor unit may be configured to generate output signals conveying information related to the power conducted through the power line to the piece of industrial equipment. The sensor unit may comprise a current monitoring circuit, a power monitoring circuit, an electrical pulse monitoring circuit, a frequency monitoring circuit and/or any other circuits. In some implementations, the sensor unit may be configured such that it is physically and logically separate and discrete from the industrial equipment and as well as from any control system configured to control the industrial equipment. For example, the sensor unit may be configured such that the it is housed in an enclosure separate from the industrial equipment and the control system does not have any means to control the sensor unit.

The processors may be configured to execute computer program modules. The executable computer program modules may include one or more of a parameter module, an analysis module, an alert module and/or any other modules. The parameter module may be configured to determine values for one or more of a power parameter based on the output signals generated by the sensor unit. The power parameters may include a duty cycle parameter, a current level parameter, a power level parameter, a voltage level parameter, a frequency level parameter, power-on duration parameter and/or any other parameters. Separate power parameter values or a set of power parameter values may be determined for the power delivered to the industrial equipment. In some implementations, power parameters may be configured on an individual industrial equipment basis as appropriate.

The analysis module may be configured to identify abnormal operation of the industrial equipment based on the parameter values as determined by the parameter module. For such an identification, the power parameter values may be compared with one or more of a threshold and/or a pattern. The identified abnormal operation of the industrial equipment may include the industrial equipment's running during scheduled down-time, running with an abnormal load (e.g., abnormally high duty cycles, abnormally high current drain, power consumed and etc.), running irregularly (e.g., irregular duty cycle, frequency, voltage level), running unscheduled operations, and/or any other abnormal operations. In some implementations, the threshold and/or pattern for determining such abnormal operations may be determined dynamically based on information about present operation of the industrial equipment. For example, the threshold and/or pattern may be determined through a function that takes as input the information of the present operation of the field equipment in real time or in near real time. In some implementations, the analysis module may be configured to receive information about present operation of the industrial equipment from a supervisory control and data acquisition system. In some embodiments, the analysis module may be configured to identify a fault of a likelihood of fault of a supervisory control and data acquisition system when information received from the supervisory control and data acquisition system indicates a different operational state than that indicated by the power information determined by the parameter module. Such a fault or likelihood of fault of the supervisory control and data acquisition system may be used to identify malfunction of the supervisory control and data acquisition system due to, e.g., intrusions, malware/virus and/or other faults through the supervisory control and data acquisition system.

The alert module may be configured to generate one or more alerts based on abnormal operations of the industrial equipment as identified by the analysis module. The alert may include information notifying a user of the abnormal operation of the industrial equipment. In some implementations where a supervisory control and data acquisition system is employed to control the industrial equipment, the alert may also include information notifying the user of likelihood that the supervisory control and data acquisition system is not working properly.

In some implementations, the processors may be coupled to sensor units through a controlled communication for security. The controlled communication may include encrypting the output signals generated by the sensor unit, transmitting the output signals through a protected communication network, and/or any other controlled communication measures. For example, the sensor unit output signals may be encrypted and transmitted on a wired network where the sensor unit is connected with the processor. In that example, the wired network may be configured such that any control system configured to control the industrial equipment does not have means to access the wired network.

### BRIEF DESCRIPTION OF THE DRAWINGS

FIG. 1 illustrates an exemplary implementation of a system for monitoring industrial equipment in accordance with one of embodiment of the disclosure.

FIG. 2 illustrates an exemplary method of monitoring industrial equipment in accordance with one of embodiment of the disclosure.

FIG. 3 illustrates another exemplary method of monitoring industrial equipment in accordance with one of embodiment of the disclosure.

### DETAILED DESCRIPTION

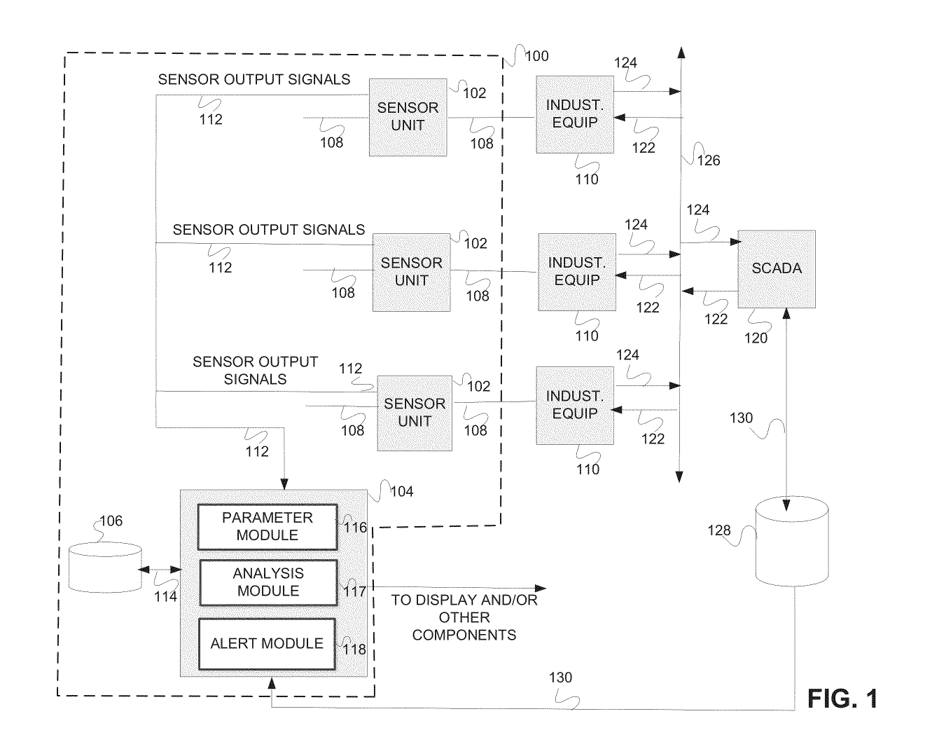

FIG. 1 illustrates an exemplary implementation of a system 100 for monitoring industrial equipment in accordance with one of embodiment of the disclosure. The system 100 may be configured such that the power conducted to the industrial equipment 110 may be measured, monitored and analyzed. Since abnormal operations, for example, such as those caused by cyber-intrusions, malware/virus, equipment failure and etc., of the industrial equipment 110 typically subjugate the industrial equipment 110 to abnormal power usage, monitoring power measurements (for example, such as power usage) of the industrial equipment 110 may provide a reliable way for detecting abnormal operations of the industrial equipment. In cases where a control and/or monitoring system, e.g., the supervisory control and data acquisition system 120 as shown, is configured to control and/or monitor the industrial equipment 110, the system 100 may also provide a redundancy to facilitate a detection of a fault or a likelihood of fault of the control and/or monitoring system. For security, the system 100 may be configured to be physically and logically separate and discreet from any control and/or monitoring system and employ a controlled communication among constituent components. As shown in this exemplary implementation, the system 100 may include one or more of a sensor unit 102, processor 104, electronic storage 106, secure communication channel 112 and/or other suitable components.

The sensor unit 102 may be configured to connected to a power line 108 that delivers electrical power to the industrial equipment 110 from a power supply or power supplies. The power supply, or power supplies, may comprise any source or sources of electrical power including, but not limited to, a remote power generation installation (e.g., a power plant and/or a power generator), a local power generation installation (e.g., one or more solar cells), a portable generator, power storage devices (e.g., batteries), capacitive storage devices, and/or any other sources. The power line 108 may include overhead power line, encapsulated electrical wire, superconducting cables, laser transmission channel, radio frequency, and/or any other suitable medium that delivers electrical power to the industrial equipment 110.

The sensor unit 102 may be configured to generate output signals—having a sensor output value—conveying information related to the power conducted through the power line 108 to the industrial equipment 110. Sensor unit 102 may comprise one or more of a current monitoring circuit, a voltage monitoring circuit, a power monitoring circuit, an electrical pulse monitoring circuit (e.g., for detection of duty cycles), a frequency monitoring circuit and/or any other suitable circuitry. In some implementations, the sensor unit may be configured to monitor one or more parameters related to power conducted to the industrial equipment 110, such as but not limited, levels of current, voltage, delivered power, frequency duty cycle, and/or any other power parameters.

In some implementations, the sensor unit 102 may be configured such that it is physically and logically separate and discrete from the industrial equipment and as well as from any control system configured to control the industrial equipment 110. For example, the sensor unit 102 may be housed in an enclosure separate from any industrial equipment. As so housed, the sensor unit 102 may operate independently from the industrial equipment 110 such that the industrial equipment 110 may be configured without capabilities to control the sensor unit 102 and alter the sensor output signal. Conversely, in some examples, the sensor unit 102 may be configured such that the sensor unit 102 may not have the capability to control the operations of the industrial equipment 110 (e.g., there is no control means such as relays from the sensor unit 102 to the industrial equipment 110), and/or may lack control over power delivered to the industrial equipment. In examples where one or more of a control system, such as the supervisory control and data acquisition system 120 as shown, is employed to control the industrial equipment 110, the sensor unit 102 may be configured such that the sensor unit 102 is not accessible from the control system—e.g., there are no connections (such as wired or wireless connections) between the sensor unit 102 and supervisory control and data acquisition system 120 that can be used to control the sensor unit 102.

As shown, the output signals generated by the sensor unit 102 may be transmitted to the processor 104 through one or more of a controlled communication channel 112. In some implementations, the sensor unit 102 may be configured to encrypt the output signal before transmitting it onto the controlled communication channel 112, e.g., through an encryption circuitry included in the sensor unit 102. The controlled communication channel 102 may include any wired and/or wireless communication channels. For example, the controlled communication channel 102 may include point-to-point wired links, such as a data bus, universal serial bus (USB) cable, firewire cable, dedicated data line, and/or any other point-to-point wired link. In another example, the controlled communication channel 112 may include wired links using a protected network communication, such as a local area network (LAN). The LAN may include one or more of a gateway and/or routers that are connected with the sensor unit 102. For protection, the gateway and/or routers may be configured such that they only transmit communications from the sensor unit 102 that are registered with the gateway and/or the routers. Such a protection may ensure that the LAN may not be intruded and/or hijacked from an outside network such as wide area network (WAN) which a supervisory control and data acquisition system typically is connected to. In some examples, the controlled communication channel 112 may include wireless links that employs one or more of gateway and/or routers configured to transmit data wirelessly. In those examples, the sensor unit 102 may be configured to include a wireless transmission circuitry that can serialize and modularize output signals into wireless signals. In some implementations, the sensor units 102 may be interconnected with each other through controlled communication channels 112 to form a meshed wired or wireless network. In those implementations, the sensor unit 102 may be configured to include circuitry that enables the sensor unit 112 to receive, send, and route the sensor output signals on the meshed network.

Also shown as included in the exemplary implementation of the system 100 is electronic storage 106, operatively connected to the processor 104 via link 114. In some implementations, the electronic storage 106 may comprise electronic storage media that electronically stores information. The electronically storage media of electronic storage 106 may include one or both of system storage that is provided integrally (i.e., substantially non-removable) with system 100 and/or removable storage that is removably connectable to the system 100 via, for example, a port (e.g., a USB port, a FireWire port, etc.) or a drive (e.g., a disk drive, etc.). Electronic storage 106 may include one or more of optically readable storage media (e.g., optical disks, etc.), magnetically readable storage media (e.g., magnetic tape, magnetic hard drive, floppy drive, etc.), electrical charge-based storage media (e.g., EEPROM, RAM, etc.), solid-state storage media (e.g., flash drive, etc.), and/or other electronically readable storage media. Electronic storage 106 may store software algorithms, information determined by processor 104, information received from the sensor unit 102 (e.g., via the processor 104), and/or other information that enables the system 100 to function properly. In some other examples, electronic storage 106 may be a separate component within system 100, or electronic storage 160 may be provided integrally with one or more other components of power management system 100 (e.g., processor 110). It should be appreciated that in some implementations of the system 100 other than the one shown in FIG. 1, the electronic storage 106 may not be included in the system 100.

Processor 104 is configured to provide information processing capabilities in the system 100. As such, processor 104 may include one or more of a digital processor, an analog processor, a digital circuit designed to process information, an analog circuit designed to process information, a state machine, and/or other mechanisms for electronically processing information. Although processor 104 is shown in FIG. 1 as a single entity, this is for illustrative purposes only. In some implementations, processor 104 may include a plurality of processing units. These processing units may be physically located within the same device, or processor 104 may represent processing functionality of a plurality of devices operating in coordination. For example, in one embodiment, the functionality attributed below to processor 110 is divided between a first processor that is operatively connected to a monitor in a device designed to be portable, or even wearable, by a user, and a second processor that communicates with the portable device at least periodically to obtain information generated by a monitor and further process the obtained information. In this embodiment, the second processor of processor 104 may include a processor provided by a host computer. Processors external to other components within the system 100 (e.g., the second processor mentioned above) may, in some cases, provide redundant processing to the processors that are integrated with components in the system 100 (e.g., the first processor mentioned above), and/or the external processor(s) may provide additional processing to determine additional information related to the operation of the system 100. In some embodiments, more than one monitor may also be included in the system 100 to provide redundancy.

The processor 104 may be configured to execute one or more computer programs. As shown, the computer programs executable on the processor 104 may include one or more of a parameter module 116, an analysis module 117, alert module 118 and/or any other modules. Processor 104 may be configured to execute modules 116, 117 and/or 118 by software; hardware; firmware; some combination of software, hardware, and/or firmware; and/or other mechanisms for configuring processing capabilities on processor 104.

It should be appreciated that although modules 116, 117 and/or 118 are illustrated in FIG. 1 as being co-located within a single processing unit, in implementations in which processor 104 includes multiple processing units, one or more of modules 116, 117 and/or 118 may be located remotely from the other modules. The description of the functionality provided by the different modules 116, 117 and/or 118 described below is for illustrative purposes, and is not intended to be limiting, as any of modules 116, 117 and/or 118 may provide more or less functionality than is described. For example, one or more of modules 116, 117 and/or 118 may be eliminated, and some or all of its functionality may be provided by other ones of modules 116, 117 and/or 118. As another example, processor 104 may be configured to execute one or more additional modules that may perform some or all of the functionality attributed below to one of modules 116, 117 and/or 118.

As shown, the parameter module 116 may be configured to determine values for one or more power parameters related to the power delivered to the industrial equipment 110 based on the output signals generated by the sensor unit 102 and/or other information. The information determined by the parameter module 116 may be used for identification of power measurements (for example, such as power usage) of the industrial equipment 110, stored in the electronic storage 106 and/or for other uses. The one or more parameters related to power delivered to the industrial equipment 110 may include a duty cycle parameter, a current level parameter, a power level parameter, a voltage level parameter, a frequency level parameter, a power-on duration parameter and/or any other parameters.

In some implementations, parameter module 116 may be configured to determine a duty cycle for the industrial equipment 110 during a reference period, e.g. a time ratio for which a motor of the industrial equipment 110 is running in the reference period. For example, a 60% duty cycle of a piece of industrial equipment could be used to indicate that the industrial equipment spends 60 seconds out of every 100 seconds in an active state of operating. The duty cycle may be determined based on the electrical pulse duration for the power delivered to the industrial equipment, as conveyed by the output signals generated by the sensor unit 102. For example, a duty cycle may be determined by dividing pulse durations from the reference period (e.g. every 100 seconds) when the pulses are detected by the sensor unit 102. The length of the reference period may be configured and stored in the electronic storage 106 during a configuration stage of the parameter module 116; or it may be dynamically established according to some pre-configured rules during a run-time of the processor 102. The determined information about a duty cycle for the industrial equipment may be used as a factor for analyzing a present operational state of the industrial equipment and stored in the electronic storage 106.

The parameter module 116 may be configured to determine a current level. For example, the output signals generated by the sensor unit 102 may convey information about a current level the industrial equipment 110 is operating at. Based on this information, an electrical power consumed by the industrial equipment may be determined as a function of the current. In some examples, the parameter module 116 may be configured to determine a voltage level based on the sensor output signals. Some industrial equipment may utilize different voltage levels for different type of operations during the reference period. In still some examples, the parameter module 116 may be configured to determine a frequency level based on the sensor output signal. Some industrial equipment may require different power frequencies for different type of operations. In yet still some other examples, the parameter module 116 may be configured to determine a duration that the industrial equipment has been powered-on. Some industrial equipment may be powered-on according to a schedule for a determined duration.

In some embodiments, a frequency of the determinations (e.g., how frequent the parameter module 116 determines power parameters for the power conducted to the industrial equipment 110 as described above), algorithms used to determine the power parameters, and/or other factors related to the determinations of the power parameters by the parameter module 116 may be determined at a configuration stage, for example during the manufacturing of system 100. In some embodiments, the factors related to the determinations of the power parameters may be determine based on user input via a user interface, based on previous and/or current power parameters determined, the type of industrial equipment involved, and/or any other suitable information. It will also be appreciated that the determinations by the parameter module 116 may be made on an individual industrial equipment basis, on a group of related industrial equipment (e.g., operate in concert for an operation however defined), and/or on a general basis for all industrial equipment coupled to system 100.

As shown, the analysis module 117 may be configured to identify abnormal operation of the industrial equipment 110 based on the power parameter values as determined by the by the parameter module 116. For such identification, the determined power parameter values may be compared with one or more thresholds and/or patterns. The thresholds and/or patterns may include expected values for power measurements (for example, such as power usage), maximum values for the power measurements, minimum values for the power measurements and/or any statistics related to the power conducted to the industrial equipment. For example, the thresholds and/or patterns may include individual and/or a combination of expected power measurements such as duty cycle, current level, voltage level, frequency level, power consumed, and/or any other measurements expected of the industrial equipment 110. Thresholds and/or patterns may include minimum acceptable values as well. For example, a pump dry may be damaged when operated dry with less than normal power consumption; and therefore a threshold of minimum acceptable value may be established to prevent the pump dry from being damaged. In some embodiments, the thresholds and/or patterns may be determined during a configuration stage of the system 100, e.g., during manufacturing, based on specifications of the industrial equipment 110, estimation by the operators of the industrial equipment, previous operational information related to power measurements (for example, such as power usage) by the industrial equipment 110 using prediction models and/or heuristic models and/or any other factors. In some embodiments, the thresholds and/or patterns may be determined dynamically based on a user input via a user interface, based on present and/or previous operation of the industrial equipment 110, and/or any other information. In some embodiments, the thresholds and/or patterns may be determined based on schedule, rules and/or events associated with the industrial equipment 110. For example, the thresholds and/or patterns may be determined based on an amount of operations the industrial equipment 110 is expected to complete according to an operation schedule of the industrial equipment 110. In those embodiments, rules may be established based on a combination of events—e.g., a rule of detecting a fault or likelihood or fault may be established when operation of the industrial equipment 110 is detected (even if the operation may be normal with a normal power usage) but a monitor of the industrial equipment reports that the industrial equipment 110 is off. In another example, the thresholds, patterns and/or rules may be established based on the time of the operations of industrial equipment 110 scheduled. For instance, the volume of the industrial equipment's operations during peak hours may be different from that during non-peak hours (e.g., holiday, night, weekend, hours). Accordingly, different thresholds, patterns, and/or rules may be established for peak-hours and non-peak hours. In some other embodiments, the thresholds and/or patterns may be determined based on known normal operations of the industrial equipment. For instance, statistical analysis may be employed to define thresholds and/or patterns under which the normal operations are found. In some embodiments, the threshold and/or pattern may be stored in the electronic storage 106.

In some implementations, thresholds and/or patterns may be configured on individual equipment 110 basis such that different thresholds and/or patterns may be used for identification of abnormal operations of industrial equipment. In some embodiments of those implementations, thresholds and/or patterns for a piece of industrial equipment 110 may be determined dynamically using a function that takes thresholds and/or patterns for another piece of industrial equipment 110 as input. For example, the thresholds and/or patterns for identification of abnormal operation of one piece of industrial equipment may be determined based on a threshold and/or pattern of power usage for another piece of equipment 110 in the case where the two pieces of industrial equipment 110 operate in a related fashion.

Based on the thresholds and/or patterns, the analysis module 117 may be configured to identify abnormal operation of the industrial equipment 110. The abnormal operation of the industrial equipment 110 may include, for example, the industrial equipment's running during scheduled down-time, running with an abnormal load (e.g. abnormally high duty cycles, abnormally high current drain, power consumed and etc.), running irregularly (e.g., irregular duty cycle, frequency, voltage level), running unscheduled operations, and/or any other abnormal operations. For example, an intrusion typically attempts to subjugate a piece of industrial equipment to abnormal operations, such as running at an extremely high load unnecessarily until the industrial equipment breaks down and/or is damaged. Such an abnormal operation may be identified by the analysis module 117 by, for example, comparing one or more power parameters of the piece of industrial equipment as determined by the parameter module with the thresholds and/or patterns based on an expected power measurements (for example, such as power usage) for normal operations of the industrial equipment.

In some implementations, the analysis module 117 may be configured to receive information 130 about a present operation of the industrial equipment 110 from a control and/or monitoring system, such as a supervisory control and data acquisition system as shown 120 in FIG. 1. However, it is noted that the supervisory control and data acquisition system 120 is illustrated in FIG. 1 merely as an example. One of ordinary skilled in the art will appreciate that the control and/or monitoring system may include any system that employs, for example but not limited to, software module, firmware, hardware logic (such as control logic), state machine, and/or any other components to control and/or monitor the industrial equipment. One of ordinary skill in the art will also appreciate that such a control and/or monitoring system may be detached from the industrial equipment or may form an integral part of the industrial equipment (e.g., a control and/or monitoring subsystem of the industrial equipment). As illustrated, the supervisory control and data acquisition system 120 may be configured to control the industrial equipment 110 using any suitable control commands 122 via a data link, such as a data bus 126 as shown. The supervisory control and data acquisition system 120 may collect information 130 about present operation of the industrial equipment 110. As shown, the supervisory control and data acquisition system 120 may employ an electronic storage 128 store the information 130 about present operation of the industrial equipment 110. In this exemplary implementation of the system 100 the processor 104 may be configured to receive information 130 via any suitable wired or wireless link, for example, but not limited to, a point-to-point wired link. However it will be appreciated, although the electronic storage 128 is a separate unit from the electronic storage 106 in this example, the electronic storage 128 and 106 may be combined to form an integrated electronic storage that is coupled to both processor 104 and the supervisory control and data acquisition system 120.

The information 130 may be used to determine abnormal operations of the industrial equipment 110. The information 130 may include general operational state of the industrial equipment 110 (e.g., type of present operations, duration of present operations and/or etc.), operational status, operational stage, specific operations the industrial equipment 110 is running and/or any other information. In some embodiments, the information 130 may be used to determine the thresholds and/or patterns that facilitates the identification of abnormal operations by the industrial equipment 110. For example, the information 130 may convey information indicating specific operations the industrial equipment 110 presently is running. Based on this information, the analysis module 117 may be configured to determine whether the information related to the power measurements (for example, such as power usage) of the industrial equipment, as determined by the parameter module, may indicate abnormal operations by the industrial equipment 110. For instance, if the information 130 indicates the industrial equipment is presently running an operation that only requires X amount of power but the power information determined by the parameter module 116 indicates that the industrial equipment 110 is consuming a greater amount of power than X, the analysis module 117 may be configured to identify that the industrial equipment 110 is running abnormally.

In some implementations, the analysis module may be configured to identify a fault or a likelihood of a fault of the supervisory control and data acquisition system 120 when the information 130 (i.e., received from the supervisory control and data acquisition system 120) indicate a different operational state than that indicated by the power information as determined by the parameter module 117. For example, in the event when the information 130 indicates the industrial equipment 110 is presently running an operation that requires X amount of power but the power information determined by the parameter module 116 indicates that the industrial equipment 110 is consuming Y amount of power, the analysis module 117 may be configured to determine whether the difference between X and Y is greater than a difference value. If the difference between X and Y is greater than the difference value, a fault or a likelihood of a fault of the supervisory control and data acquisition system 120 may be identified. The difference value may be configured to account for a tolerable deviation between the supervisory control and data acquisition system 120 and the system 100. In some embodiments, the difference value may be set much greater than the normal deviation between the system 100 and supervisory control and data acquisition system 120. Such a difference value may be used to trigger identification of a likelihood that the supervisory control and data acquisition system 120 is at a fault due to a cyber-attack. The difference value may be stored in the electronic storage 106. In some embodiments, the difference value may also be determined dynamically based on, for example, user input via a user interface.

As shown, the alert module 118 may be configured to generate one or more alerts based on abnormal operations of the industrial equipment 110 as identified by the analysis module 118. The alerts may include information notifying a user of the abnormal operations of the industrial equipment. For example, the alerts may notify the user that the industrial equipment 110 is operating at a scheduled down-time, is operating with an abnormally high load, is operating irregularly, is operating unscheduled operations, and/or any other abnormal operations of the industrial equipment 110. In some examples where a control system, such as the supervisory control and data acquisition system 120 is configured to control the industrial equipment, the alerts may include information indicating a fault or a likelihood of a fault of the control system. For example, as described above, in events when the information 130 indicates a different operational state of the industrial equipment than that indicated by the power information as determined by the parameter module 116, the alert module 118 may be configured to generate alerts notifying the user that the control system, such as the supervisory control and data acquisition system 120, may be working improperly. In some implementations, the alert module 118 may also be configured to generate alerts to notify the user that the industrial equipment 110 is running normally according to the power information as determined by the system 100 when the supervisory control and data acquisition system 120 indicates otherwise. This may help reduce false alarms caused by the supervisory control and data acquisition system 120.

The alerts may include text representations and/or graphical representations of information conveying the notifications as described above. Such alerts may be displayed on a display either included in or detached from system 100. The display may be located in a control center side by side with other information regarding the industrial equipment, e.g., information 130 as collected by the supervisory control and data acquisition system 120. In some implementation, the display may be located separately from the control system (e.g., in a location not accessible from the control center). In some implementations, the alerts may include output values sent to other modules of system 100 and/or the control system such as supervisory control and data acquisition system 120, via a program interface coupled with the alert module 118.

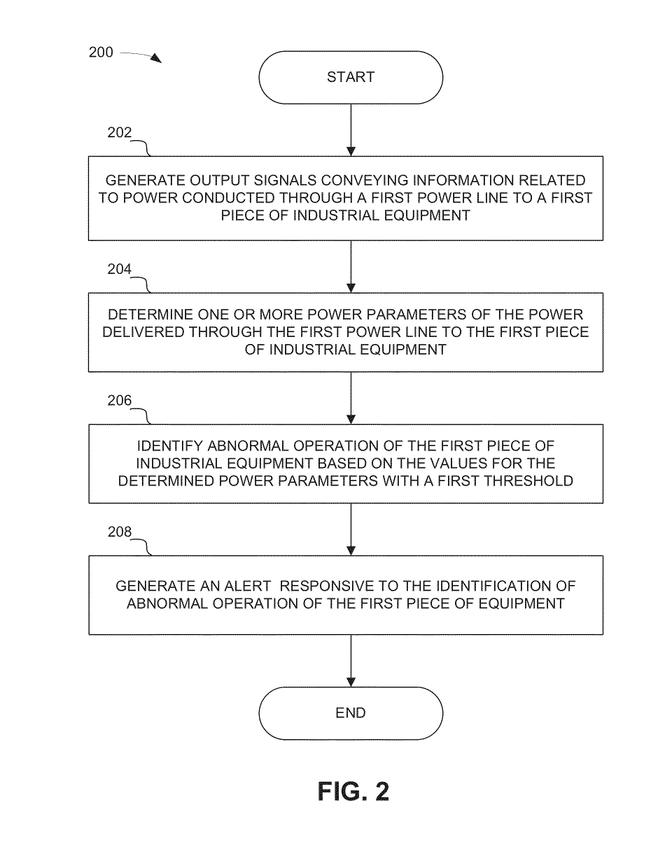

FIG. 2 illustrates one exemplary method 200 of monitoring industrial equipment in accordance with one embodiments of the disclosure. The operations of method 200 presented below are intended to be illustrative. In some embodiments, method 200 may be accomplished with one or more additional operations not described, and/or without one or more of the operations discussed. Additionally, the order in which the operations of method 200 are illustrated in FIG. 2 and described below is not intended to be limiting. The order of the operations shown in FIG. 2 may vary in some other examples.

In some embodiments, method 200 may be implemented in one or more sensor units and processors (e.g., a digital processor, an analog processor, a digital circuit designed to process information, an analog circuit designed to process information, a state machine, and/or other mechanisms for electronically processing information), such those the sensor units 102 and processor 104 as described above, or those that are substantially similar to the sensor units 102 and processor 104 as described above. Method 200 will be described with references to FIG. 1. The one or more processor may include one or more devices executing some or all of the operations of method 200 in response to instructions stored electronically on an electronic storage medium, such as the electronic storage 106 as described above. The one or more processor may include one or more devices configured through hardware, firmware, and/or software to be specifically designed for execution of one or more of the operations of method 200.

At operation 202, sensor output signals is generated to convey information related to power conducted through a first power line to a first piece of industrial equipment. For example, a sensor unit such as the senor unit substantially similar to or the same as sensor unit 102 as shown in FIG. 1 may be used to generate the output signals as described above.

At operation 204, one or more power parameters of the power delivered through the first power line to the first piece of industrial equipment is determined. In one embodiment, operation 204 may be performed by a parameter module substantially similar to or the same as the parameter module 116 (shown in FIG. 1 and described above).

At operation 206, abnormal operation of the first piece of industrial equipment is identified based on the values for the determined power parameters with a first threshold. In one embodiment, operation 206 may be performed by an analysis module substantially similar to or the same as the analysis module 117 (shown in FIG. 1 and described above).

At operation 208, an alert is generated responsive to the identification of abnormal operation of the first piece of equipment. In one embodiment, operation 208 may be performed by an alert module substantially similar to or the same as the alert module 118 (shown in FIG. 1 and described above).

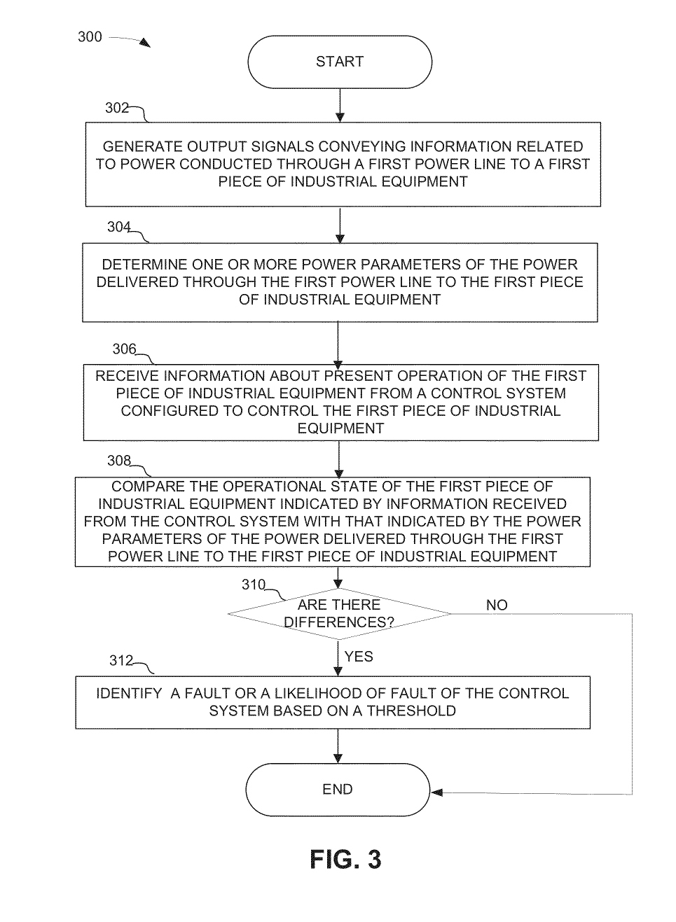

FIG. 3 illustrates one exemplary method 200 of monitoring industrial equipment in accordance with one or more embodiments of the disclosure. The operations of method 300 presented below are intended to be illustrative. In some embodiments, method 300 may be accomplished with one or more additional operations not described, and/or without one or more of the operations discussed. Additionally, the order in which the operations of method 300 are illustrated in FIG. 3 and described below is not intended to be limiting. The order of the operations shown in FIG. 3 may vary in some other examples.

In some embodiments, method 300 may be implemented in one or more sensor units and processors (e.g., a digital processor, an analog processor, a digital circuit designed to process information, an analog circuit designed to process information, a state machine, and/or other mechanisms for electronically processing information). Method 300 will be described with references to FIG. 1. The one or more processor may include one or more devices executing some or all of the operations of method 200 in response to instructions stored electronically on an electronic storage medium, such as the electronic storage 106 as described above. The one or more processor may include one or more devices configured through hardware, firmware, and/or software to be specifically designed for execution of one or more of the operations of method 300.

At operation 302, sensor output signals is generated to convey information related to power conducted through a first power line to a first piece of industrial equipment. For example, a sensor unit such as the senor unit substantially similar to or the same as sensor unit 102 as shown in FIG. 1 may be used to generate the output signals as described above.

At operation 304, one or more power parameters of the power delivered through the first power line to the first piece of industrial equipment is determined. In some embodiments, operation 304 may be performed by a parameter module substantially similar to or the same as the parameter module 116 (shown in FIG. 1 and described above).

At operation 306, information about present operation of the first piece of industrial equipment from a control system configured to control the first piece of industrial equipment may be received. In some embodiments, operation 306 may be performed by an analysis module substantially similar to or the same as the parameter module 117 (shown in FIG. 1 and described above).

At operation 308, the operational state of the first piece industrial equipment indicated by the information received from the control system may be compared with that indicated by the power parameters of the power delivered through the first power line to the first piece of industrial equipment. In some embodiments, operation 308 may also be performed by an analysis module substantially similar to or the same as the parameter module 117 (shown in FIG. 1 and described above).

At decision block 310, the difference between the operational state of the first piece industrial equipment indicated by the information received from the control system and that indicated by the power parameters of the power delivered through the first power line to the first piece of industrial equipment may be recognized. In some examples, the method 300 does not recognize such differences and proceeds to the end of the processing of method 300. In some examples, the method 300 recognizes such differences exist and proceeds to operation 310.

At operation 312, a fault or a likelihood of fault of the control system based on a threshold and/or pattern may be identified. In some embodiments, operation 312 may be by an analysis module substantially similar to or the same as the parameter module 117 (shown in FIG. 1 and described above).

In the claims, any reference signs placed between parentheses shall not be construed as limiting the claim. The word “comprising” or “including” does not exclude the presence of elements or steps other than those listed in a claim. In a device claim enumerating several means, several of these means may be embodied by one and the same item of hardware. The word “a” or “an” preceding an element does not exclude the presence of a plurality of such elements. In any device claim enumerating several means, several of these means may be embodied by one and the same item of hardware. The mere fact that certain elements are recited in mutually different dependent claims does not indicate that these elements cannot be used in combination.

Although the invention has been described in detail for the purpose of illustration based on what is currently considered to be the most practical and preferred embodiments, it is to be understood that such detail is solely for that purpose and that the invention is not limited to the disclosed embodiments, but, on the contrary, is intended to cover modifications and equivalent arrangements that are within the spirit and scope of the appended claims. For example, it is to be understood that the present invention contemplates that, to the extent possible, one or more features of any embodiment can be combined with one or more features of any other embodiment.

What is claimed is:

1. A system for monitoring industrial equipment, the system comprising:
a first sensor unit configured to be coupled to a first power line that conducts power to a first piece of industrial equipment, the first sensor further being configured to generate output signals conveying information related to the power conducted through the first power line to the first piece of industrial equipment; and
one or more processors configured to execute computer program modules, the computer program modules comprising:
a parameter module configured to determine one or more power parameters of the power delivered through the first power line to the first piece of industrial equipment;
an analysis module configured to identify abnormal operation of the first piece of industrial equipment by comparing a first power parameter of the power delivered through the first power line to the first piece of industrial equipment, as determined by the parameter module, with a first threshold and/or pattern; and
an alert module configured to generate an alert responsive to the identification of abnormal operation of the first piece of equipment by the analysis module.

2. The system of claim 1, wherein the first sensor unit is separate and discrete from the first piece of industrial equipment, and is separate and discrete from any control and/or monitoring system configured to control and/or monitor the first piece of equipment.

3. The system of claim 1, wherein the analysis module is configured such that the first threshold and/or pattern is determined dynamically based on information about present operation of the first piece of equipment.

4. The system of claim 3, wherein the analysis module is configured to receive information about a present operation of the first piece of equipment from a control and/or monitoring system.

5. The system of claim 4, wherein the analysis module is further configured to identify a fault or a likelihood of a fault of the control and/or monitoring system based on the information about the present operation of the first piece of equipment received from the supervisory control and data acquisition system and the power parameters determined by the parameter module.

6. The system of claim 1, further comprising a second sensor unit configured to be coupled to a second power line that conducts power to a second piece of industrial equipment, the second sensor further being configured to generate output signals conveying information related to the power conducted through the second power line to the second piece of industrial equipment, wherein the parameter module is further configured to determine one or more power parameters of the power delivered through the second power line to the second piece of industrial equipment, wherein the analysis module is further configured to identify abnormal operation of the second piece of industrial equipment by comparing the first power parameter of the power delivered through the second power line to the second piece of industrial equipment, as determined by the parameter module, with a second threshold and/or pattern, and wherein the alert module is further configured to generate an alert responsive to identification of abnormal operation of the second piece of equipment by the analysis module.

7. The system of claim 1, wherein the analysis module is further configured to identify abnormal operation of the first piece of industrial equipment by comparing a second power parameter of the power delivered through the first power line to the first piece of industrial equipment, as determined by the parameter module, with a second threshold and/or pattern.

8. The system of claim 7, wherein the analysis module is further configured such that the second threshold is determined dynamically as a function of the first power parameter.

9. The system of claim 1, wherein the processors are coupled to the first sensor unit through a controlled communication.

10. The system of claim 9, wherein the controlled communication comprises encrypting the output signals generated by the first sensor unit.

11. The system of claim 10, wherein the controlled communication comprises transmitting output signals generated by the first sensor through a protected communication network.

12. The system of claim 1, wherein the first sensor unit comprises at least one of:
a current monitoring circuit;
a voltage monitoring circuit;
a power monitoring circuit;
an electrical pulse monitoring circuit; and
a frequency monitoring circuit;

13. A method for monitoring industrial equipment using a first sensor unit and one or more processors configured to execute computer program modules, the computer program modules comprising a parameter module, an analysis module and an alert module, the method comprising:
generating with the first sensor unit output signals conveying information related to power conducted through a first power line to a first piece of industrial equipment using a first sensor unit configured to be coupled to the first power line;
determining one or more power parameters of the power delivered through the first power line to the first piece of industrial equipment with the parameter module;
identifying abnormal operation of the first piece of industrial equipment with the analysis module by comparing a first power parameter of the power delivered through the first power line to the first piece of industrial equipment, as determined by the parameter module, with a first threshold and/or pattern; and
generating an alert with the alert module responsive to the identification of abnormal operation of the first piece of equipment by the analysis module.

14. The method of claim 13, wherein the first sensor unit is separate and discrete from the first piece of industrial equipment, and is separate and discrete from any control and/or monitoring system configured to control and/or monitor the first piece of equipment.

15. The method of claim 13, further comprising determining the first threshold and/or pattern dynamically based on information about present operation of the first piece of equipment.

16. The method of claim 15, wherein the information about present operation of the first piece of equipment is received from a control and/or monitoring system.

17. The method of claim 16, further comprising identifying a fault or a likelihood of a fault of the control and/or monitoring system based on the information about the present operation of the first piece of equipment received from the supervisory control and data acquisition system and the power parameters as determined by the parameter module.

18. The method of claim 13 further using a second unit and further comprising:
generating with the second sensor unit output signals conveying information related to power conducted through a second power line to a second piece of industrial equipment using a second sensor unit configured to be coupled to the second power line;
determining one or more power parameters of the power delivered through the second power line to the second piece of industrial equipment with the parameter module;
identifying abnormal operation of the second piece of industrial equipment with the analysis module by comparing a second power parameter of the power delivered through the second power line to the second piece of industrial equipment, as determined by the parameter module, with a second threshold and/or pattern; and
generating an alert with the alert module responsive to the identification of abnormal operation of the second piece of equipment by the analysis module.

19. The method of claim 13, wherein the identification of the abnormal operation of the first piece of industrial equipment comprises comparing a second power parameter of the power delivered through the first power line to the first piece of industrial equipment, as determined by the parameter module, with a second threshold and/or pattern.

20. The method of claim 19, further comprising determining the second threshold and/or pattern with the analysis module dynamically as a function of the first power parameter.

21. The method of claim 13, wherein the processors are coupled to the first sensor unit through a controlled communication.

22. The method of claim 21, wherein the controlled communication comprises encrypting the output signals generated by the first sensor unit.

23. The method of claim 22, wherein the controlled communication comprises transmitting output signals generated by the first sensor through a protected communication network.

24. The method of claim 13, wherein the first sensor unit comprises at least one of:
a current monitoring circuit;
a voltage monitoring circuit;
a power monitoring circuit;
an electrical pulse monitoring circuit; and
a frequency monitoring circuit;
